(19) United States
(12) Patent Application Publication
(10) Pub. No.: US 2006/0176198 A1
(43) Pub. Date: Aug. 10, 2006

(54) DIGITIZATION OF VIDEO AND OTHER TIME BOUNDED SIGNALS

(75) Inventor: John Doty, Pine, CO (US)

Correspondence Address: GLENN L. WEBB, P.O BOX 951, CONIFER, CO, 80433, US

(73) Assignee: NOQSI AEROSPACE LTD, Pine, CO (US)

(21) Appl. No.: 11/307,435

(22) Filed: Feb. 7, 2006

Related U.S. Application Data
(60) Provisional application No. 60/593,718, filed on Feb. 8, 2005.

(51) Int. Cl. H03M 3/00

(52) U.S. Cl. 341/143

(57) ABSTRACT

An analog to digital processor for time bounded signals. The present invention provides a processor that is capable of processing time bounded signals through a delta sigma modulator. The present invention provides a gate or premodulator to limit the input the application of a time bounded input signal to the digitizer only during the time bounds of the signal. This provides optimum filtering of both the input signal and the modulator output while preserving the benefits of the delta sigma approach.

### FIELD OF THE INVENTION

This invention relates to the field of converting analog signals to digital signals.

### BACKGROUND OF THE INVENTION

Media content as well as other types of content are typically created in analog format, such as film, tape, and other analog formats. It is often necessary to convert that format to a digital form to enable the use of most modern playback devices, for further processing, for transmission as well as many other needs. Thus the need for analog to digital conversion systems and processes is critical.

Analog to digital conversion is an electronic process that changes a continuous variable analog signal without altering its content into multilevel discrete digital signals. There are a number of techniques currently used for analog to digital conversions. These techniques include flash analog to digital conversion; successive approximates, pipeline analog to digital conversion, folding analog to digital conversion as well as many other types. These processes tend to require extensive processing capability in order to achieve adequate conversion of the analog signal to a digital signal.

One technique that has previously been used for converting audio signals to digital audio is delta sigma digitization. This approach generally provides excellent linearity, precision and noise rejection for non-time bounded signals. Delta Sigma modulation uses oversampling of the input signal along with noise shaping to achieve a high level of resolution. Typically, a conventional Delta Sigma digitizer has the structure as shown in FIG. 1 with analog modulator 10 and digital filter 20.

The Delta Sigma modulator converts the input signal into a sequence of low precision. Typically this signal is a one bit signal. This signal is averaged to represent the level at the analog input. The digital decimation filter recovers a precise digital representation of the input by computing a weighted average of the low precision numbers from the modulator.

This approach is widely used in applications like digital audio where the phase and frequency response of the digitizer are tightly constrained, but the time domain response is not. The digital filter's impulse response must approach zero slowly and smoothly to remove the noise from the modulator's output. If the signal to be measured is sharply bounded in time (like a video pixel), the resulting long tailed impulse response is troublesome: if it's narrow enough to fit within the time bounds, its bandwidth will be excessive. If it matches the signal bandwidth, the wings will bring in unwanted influences from outside the time bounds of the signal.

Another problem occurs with the existing delta sigma analog to digital converters. The noise shaping filter stability is critical. If the noise shaping filter is unstable, the conversion will not take place properly.

Thus there presently is a need for a digitization process that will digitize time bounded signals such as video through a delta sigma processor without compromising the characteristics of linearity, precision and noise rejection.

### SUMMARY OF THE INVENTION

The present invention solves these and other needs by providing a digitization process that digitizes time bounded analog signals. The process utilizes a delta sigma digitization process that is stable and precise and does not substantially increase the overhead of the digitization process.

The present invention in a preferred embodiment provides a gate before the analog signal reaches the delta sigma modulator. The analog signal does not reach the modulator until the gate opens. The gate prevents spurious signals from outside the time bounds of the signal.

The gate of a preferred embodiment resets the state of the modulator to prevent the residue of the signal from being processed. This enables the process to work with an unstable signal without failure.

In another preferred embodiment, the gate yields an output proportional to the signal during an averaged time segment and zero before and after the averaged time segment.

In another preferred embodiment, a premodulator is used in place of the gate. This allows the digitizer to measure an arbitrarily weighted integral over the incoming signal, with weights selectable independently of the needs of the digital filter following the modulator.

These and other features will be evident from the ensuing detailed description of embodiments and from the drawings.

### BRIEF DESCRIPTION OF THE DRAWINGS

FIG. 1 is a schematic representation of a typical delta sigma modulation processor.

FIG. 2 is a schematic representation of a preferred embodiment of the present invention.

FIG. 3 is a schematic representation of another preferred embodiment of the present invention.

### DETAILED DESCRIPTION OF PREFERRED EMBODIMENTS

The present invention provides systems and process for providing an analog to digital digitization of video and other time bounded signals. Preferred embodiments of these systems and processes are discussed below. It is to be expressly understood that this descriptive embodiment is provided for explanatory purposes only and is not meant to limit the scope of the claimed invention. Other types and uses of the systems and processes are also considered to be within the scope of the present invention.

A preferred embodiment of the present invention provides a digitization process and system for video and other time bounded signals. Time bounded signals such as video pose a significant challenge in digitizing analog signals. Typical digitization processes such as delta sigma digitizers are not able to process time bounded signals due to the lack of constraints on the time domain response. The decimation filter has a normally having a resulting long tailed impulse response. If this response is narrow enough to fit with the time bounds, the bandwidth of the filter will be excessive. If the filter matches the signal bandwidth, then the “wings” of the filter's temporal response will bring in unwanted influences from outside the time bounds of the signal.

A preferred embodiment of the present invention provides a gate ahead of the delta sigma modulator. Gating the signal ahead of modulator can prevent the spurious response from outside the time bounds of the signal, while allowing a wide digital filter impulse response. The effective input-referred impulse response of the system is the product of the time reversal of the gating function with the digital filter impulse response, with the alignment determined by when the output of the digital filter is sampled.

This opens up a number of opportunities for simplification and optimization. The signal is only applied to the Delta Sigma modulator when the gate is open. Before the gate is open, the modulator is processing its error residue left from the previous conversion. If the modulator is preset to a known state just before the gate opens, this phase of its operation, and the corresponding falling tail of the digital filter's impulse response, may be eliminated. After the gate closes, the modulator processes the error residue from the current conversion. As in a conventional Delta Sigma digitizer, this may be fed to the digital filter, to be processed by the leading edge of its impulse response. Alternatively, the residual error signal may be fed to a separate digitizer and the Delta Sigma modulator may then be reset to allow it to immediately begin integrating another window (in this case, the gate need not be present).

One important feature of the preferred embodiment of the present invention is the minimization of the effect of the noise shaping filter instability. The stability of the noise shaping filters is critical in conventional delta sigma converters. The gate of the preferred embodiment of the present invention resets the state of the noise shaping filter between conversions. Thus an unstable noise shaping filter may degrade the performance somewhat but will not cause failure.

One application of this preferred embodiment is discussed below. It is to be expressly understood that other applications of the present invention are within the scope of the present invention. This descriptive embodiment is presented for explanatory purposes only and is not meant to limit the scope of the present invention.

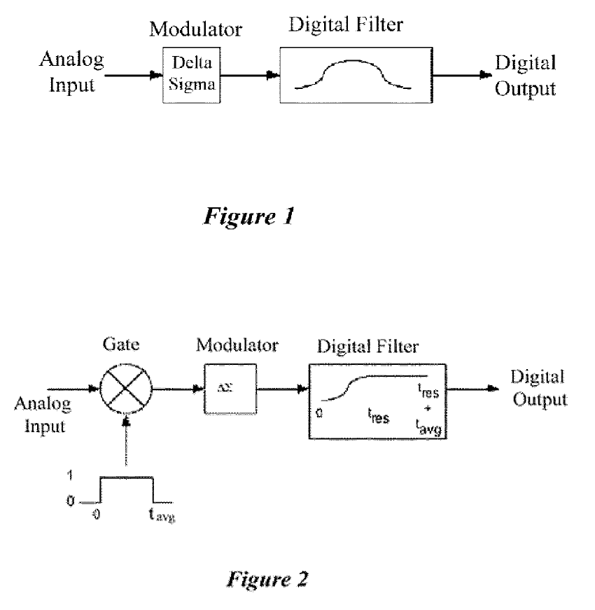

The simplest application of this idea is a “boxcar” averaging digitizer as shown in FIG. 2. Here, the gate yields an output proportional to the signal during from time 0 to time tavg, and zero before and after. The impulse response of the decimation filter consists of a rising segment, of duration tres, whose function is to determine the residual charge in the Delta Sigma modulator's signal integration capacitor after the signal averaging interval, and a flat top that averages the signal during the signal averaging interval. If the state of the Delta Sigma modulator is preset before the measurement, the filter's impulse response needs no falling tail.

A simulation of this embodiment assumes a second order feedback Delta Sigma modulator feeding a digital filter with a flat averaging response and a sinusoidal residual response, as shown above. The duty cycle was 50%: tavg and tres were each 96 samples in duration. RMS digitization error was 0.023% of full scale, which was chosen to be 90% of the modulator saturation level.

A more general case would involve a “premodulator” in place of the gate. This allows the digitizer to measure an arbitrarily weighted integral over the incoming signal, with weights selectable independently of the needs of the digital filter following the modulator.

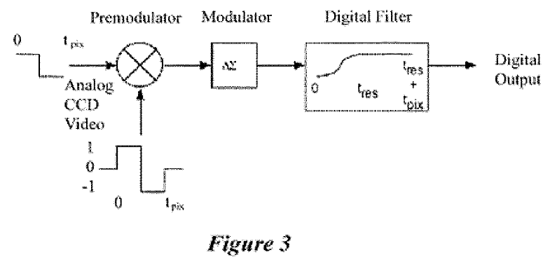

With simple bipolar premodulation, this approach implements an “integrating correlated double sampler” for digitizing CCD video. A schematic of this approach is shown in FIG. 3.

This effectively subtracts the integral of the signal after the video clock transition from the integral of the signal before the video clock transition to cancel the residual charge noise (“kTC” noise) that is present in the CCD output signal.

A preferred embodiment of an application of a gated Delta Sigma modulation system for processing video signals uses multiple sets of the gated Delta Sigma converters. This application can be provided on an integrated chip or other semiconductor device. The system will include eight modulators that serve four video channels. A separate preamplifier provides input to each pair of modulators. Each pair of modulators serves a separate video channel. This allows each pair of modulators to take turns integrating the video. This leaves time to process the residual analog signal as discussed above. The decimation filter will be implemented with an external device such as a computer or specialized integrated chip.

In a preferred embodiment of the present invention, a delta sigma modulator in a 0.35 μm mixed-signal CMOS process achieves the following specifications:

Video full scale: 20 mV; Digitizer noise: <10 μV RMS; Integral nonlinearity: <0.1% of full scale; Differential nonlinearity: <0.01% of full scale; Pixel rate: up to 1 million/second/channel; Power: <50 mW for four channels.

The sample rate for this modulator for this preferred embodiment is 160 samples per pixel with 80 for video and 80 for shaping filter residuals for a 12 bit conversion using an optimized noise shaping filter.

In conclusion, simply applying a time bounded input signal to a Delta Sigma modulator only within the signal's time bounds can lead to digitizer architectures that reduce conversion time and allow optimum filtering of both the input signal and the modulator output, while preserving the usual benefits of the Delta Sigma approach.

It is to be expressly understood that the above descriptive embodiments are not meant to limit the scope of the present invention. The descriptive embodiments are provided for explanatory purposes only. Other embodiments are considered to be within the scope of the present invention. For example and without limitation, the present invention may be applied to converting analog signals such as not only video but optical or x-ray videos, digital photography and cinematography and other time bounded signals as well as other applications not limited to time bounded signals.

What is claimed is:

1. An analog to digital conversion process wherein said process comprises:
providing a delta sigma modulation processor;
providing a digital filter for receiving a signal from said delta sigma modulation processor;
providing a gate prior to said delta sigma modulation processor for applying a time bounded input signal to said delta sigma modulator only with the time bounds of the signal.

2. The process of claim 1 wherein said step of providing a gate includes:
processing the error residue from the current conversion while said gate is closed.

3. The process of claim 1 wherein said state of providing a gate includes:
resetting said modulator to a known state just prior to the opening of the gate.

4. The process of claim 1 wherein said state of providing a gate includes:
resetting said modulator to a known state just prior to the opening of the gate to eliminate the processing of the error residue from the previous conversion to prevent it from being fed to said digital filter.

5. The process of claim 1 wherein said step of providing a gate includes:
said gate yielding an output proportion to the signal during an averaged time segment and zero before and after the averaged time segment.

6. The process of claim 1 wherein said step of providing a gate includes:
a premodulator to allow the digitizer to measure an arbitrarily weighted integral over the incoming signal.

7. The process of claim 1 wherein said process includes the steps of:
using 160 samples for a 12 bit conversion process.

8. The process of claim 1 wherein said process includes:
each of said set of modulation processors, digital filter and gate forms a converter; and
providing multiples of said converters to process an analog signal.

9. An analog to digital converter wherein said process comprises:
a delta sigma modulation processor;
a digital filter for receiving a signal from said delta sigma modulation processor; and
a gate prior to said delta sigma modulation processor for applying a time bounded input signal to said delta sigma modulation processor only with the time bounds of the signal.

10. The analog to digital converter of claim 9 wherein:
each of said set of modulation processors, digital filter and gate forms a separate converter; and
multiples of said converters are utilized together in sequence to process an analog signal.
